(19) United States
(12) Patent Application Publication
(10) Pub. No.: US 2008/0079108 A1
(43) Pub. Date: Apr. 3, 2008

(54) Method for Improving Sensitivity of Backside Illuminated Image Sensors

(75) Inventors: Tzu-Hsuan HSU, Kaohsiung City (TW); Dun-Nian YAUNG, Taipei City (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/774,681

(22) Filed: Jul. 9, 2007

Related U.S. Application Data
(60) Provisional application No. 60/827,611, filed on Sep. 29, 2006.

(51) Int. Cl. H01L 31/00; H01L 21/02

(52) U.S. Cl. 257/460; 438/57; 257/E31.053; 257/E21.04

(57) ABSTRACT

A method for improving sensitivity of backside illuminated image sensor. A substrate having a first conductivity type and a first potential. A depletion region having a second conductivity type is formed within the substrate. The depletion region is extended. The thickness of the substrate is reduced. First type conductivity ions having a second potential are implanted at backside surface of the substrate to form a doping layer. Laser annealing on the doping layer is performed to activate the first type conductivity ions.

### CROSS REFERENCE

This application claims priority to U.S. Provisional Patent Application Ser. No. 60/827,611, filed on Sep. 29, 2006.

### BACKGROUND

An image sensor provides a grid of pixels, such as photosensitive diodes or photodiodes, reset transistors, source follower transistors, pinned layer photodiodes, and/or transfer transistors, for recording an intensity or brightness of light. The pixel responds to the light by accumulating a charge—the more light, the higher the charge. The charge can then be used by another circuit so that a color and brightness can be used for a suitable application, such as a digital camera. Common types of pixel grids include a charge-coupled device (CCD) or complimentary metal oxide semiconductor (CMOS) image sensor.

Backside illuminated sensors are used for sensing a volume of exposed light projected towards the backside surface of a substrate. The pixels are located on a front side of the substrate, and the substrate is thin enough so that light projected towards the backside of the substrate can reach the pixels. Backside illuminated sensors provide a high fill factor and reduced destructive interference, as compared to front-side illuminated sensors.

A problem with backside illuminated sensors is that since the light illuminates from the backside surface, it is difficult to collect electrons generated near the backside surface. Particularly, it is difficult to collect electrons generated from blue light. Another problem with backside illuminated sensors is that non-uniform thickness of the residual substrate causes photo response non-uniformity. For example, if the thickness of the residual substrate is increased from 4 um to 4.2 um, backside non-uniformity is induced because the distance between the junction depth and the backside surface is also increased. As a result, the electrons have to travel much farther to reach the photodiodes.

One method to alleviate this backside surface non-uniformity problem is by implanting a fully depleted p-type region within the substrate. A fully depleted region may extend from the front side of the substrate fully to the backside surface of the substrate. However, high energy ion implantation used to extend the depletion region often impacts performance and causes leakage current to the devices.

Another method to alleviate the backside surface non-uniformity problem is to increase the resistance of the p-type substrate. However, with the introduction of a p+ substrate in the backside surface, the p+ substrate out diffuses into the p− substrate as resistance increases. This provides poor photo sensitivity.

A need exists for a method that provides a backside illuminated sensor with good photo sensitivity without affecting the performance of the devices and the concerns of out diffusion.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a top view of a sensor device including a plurality of pixels, according to one or more embodiments of the present invention.

FIG. 2 is a sectional view of a sensor having a plurality of backside illuminated pixels, constructed according to aspects of the present disclosure.

FIG. 3 is a sectional view of a sensor with a p+ pinned layer implanted.

FIG. 4 is a sectional view of a sensor with an extended depletion region and a shallow p+ layer implanted.

FIG. 5 is a flowchart of an exemplary process for improving the sensitivity of a backside illuminated image sensor.

FIG. 6 is a graph illustrating electrons detected by the sensor based on different light wavelengths.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

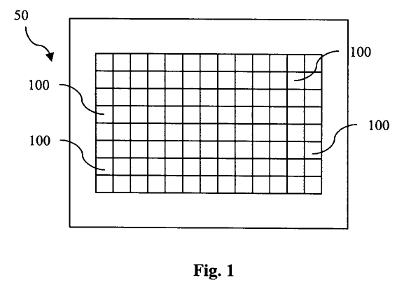

Referring to FIG. 1, an image sensor 50 provides a grid of backside illuminated (or back-illuminated) pixels 100. In the present embodiment, the pixels 100 are photosensitive diodes or photodiodes, for recording an intensity or brightness of light on the diode. The pixels 100 may include reset transistors, source follower transistors, pinned layer photodiodes, and transfer transistors. The image sensor 50 can be of various different types, including a charge-coupled device (CCD), a complimentary metal oxide semiconductor (CMOS) image sensor (CIS), an active-pixel sensor (ACP), or a passive-pixel sensor. Additional circuitry and input/outputs are typically provided adjacent to the grid of pixels 100 for providing an operation environment for the pixels and for supporting external communications with the pixels.

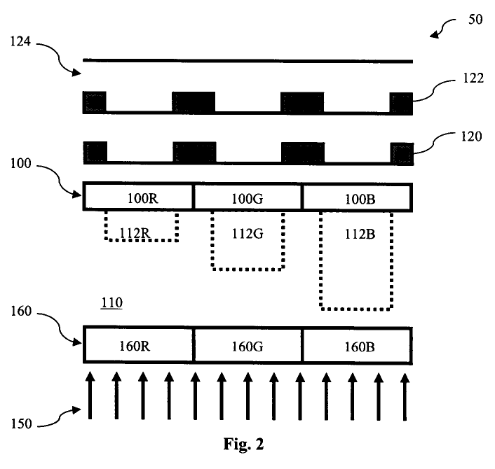

Referring now to FIG. 2, the sensor 50 includes a p-silicon substrate 110. Alternatively, the substrate 110 may comprise an elementary semiconductor such as silicon, germanium, and diamond. The substrate 110 may also comprise a compound semiconductor such as silicon carbide, gallium arsenic, indium arsenide, and indium phosphide. Also, semiconductor arrangements such as silicon-on-insulator and/or an epitaxial layer can be provided. The substrate 110 may comprise an alloy semiconductor such as silicon germanium, silicon germanium carbide, gallium arsenic phosphide, and gallium indium phosphide. In the present embodiment, the substrate 110 comprise P-type silicon. All doping may be implemented using a process such as ion implantation or diffusion in various steps. Different dopings, including p type or n-type, may be used. The substrate 110 may comprise lateral isolation features to separate different devices formed on the substrate.

The sensor 50 includes a plurality of pixels 100 formed on the front surface of the semiconductor substrate 110. For the sake of example, the pixels are further labeled 100R, 100G, and 100B to correspond with example light wavelengths of red, green, and blue, respectively. The pixels 100 each comprise a light-sensing region (or photo-sensing region) which in the present embodiment is an N-type depletion region 112 having dopants formed in the semiconductor substrate 110 by a method such as diffusion or ion implantation. In continuance of the present example, the doped regions are further labeled 112R, 112G, and 112B to correspond with the pixels 100R, 100G, and 100B, respectively.

The sensor 50 further includes additional layers, including first and second metal layers 120, 122 and inter-level dielectric 124. The dielectric layer comprises a low-k material, as compared to a dielectric constant of silicon dioxide. Alternatively, the dielectric layer 124 may comprise carbon-doped silicon oxide, fluorine-doped silicon oxide, silicon oxide, silicon nitride, and/or organic low-k material. The material of metal layers 120 and 122 may include aluminum, copper, tungsten, titanium, titanium nitride, tantalum, tantalum nitride, metal silicide or combination thereof.

Additional circuitry also exists to provide an appropriate functionality to handle the type of pixels 100 being used and the type of light being sensed. It is understood that the wavelengths red, green, and blue are provided for the sake of example, and that the pixels 100 are generally illustrated as being photodiodes for the sake of example.

The sensor 50 is designed to receive light 150 directed towards the back surface of the semiconductor substrate 110 during applications, eliminating any obstructions to the optical paths by other objects such as gate features and metal lines, and maximizing the exposure of the light-sensing region to the illuminated light. The substrate 110 may be thinned such that the light 150 directed through the back surface thereof may effectively reach on the photodiodes. The illuminated light 150 may not be limited to visual light beam, but can be infrared (IR), ultraviolet (UV), and other radiation beam.

The sensor 50 further comprises a color filter layer. The color filter layer can support several different color filters (e.g., red, green, and blue), and may be positioned such that the incident light is directed thereon and there through. In one embodiment, such color-transparent layers may comprise a polymeric material (e.g., negative photoresist based on an acrylic polymer) or resin. The color filter layer may comprise negative photoresist based on an acrylic polymer including color pigments. In continuance of the present example, color filters 160R, 160G, and 160B correspond to pixels 100R, 100G, and 100B, respectively.

The sensor 50 may comprise a plurality of micro-lens interposed between the pixels 100 and the back surface of the semiconductor substrate 110, or between the color filters 160 and the back surface of substrate 110 or between the color filters 160 and the air if the color filters are implemented, such that the backside-illuminated light can be focused on the light-sensing regions.

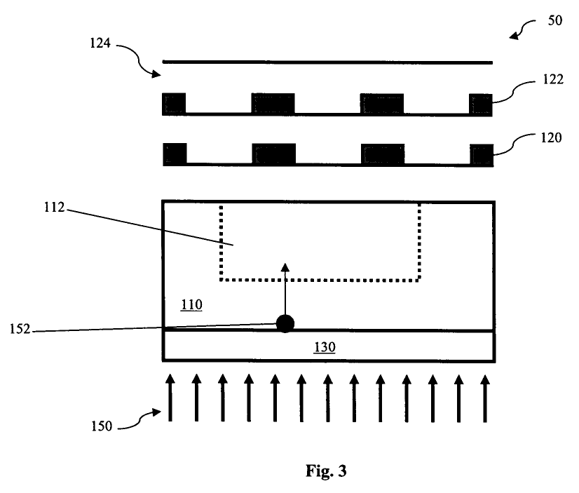

Referring to FIG. 3, a backside illuminated sensor with a shallow p+ pinned layer is depicted. In this illustrative example, a shallow pinned p+ layer 130 is the original p+ substrate. Shallow pinned p+ layer 130 is formed by implanting p+ ions on the backside surface of substrate 110. The shallow pinned p+ layer 130 is applied against the p− substrate 110. The shallow pinned p+ layer 130 has a thickness of less than about 1 um.

When light 150 is directed through the back surface of the semiconductor substrate 110, electrons 152 are absorbed by the substrate 110 before reaching photodiode. A problem exists when a blue light is directed through the residual substrate 110, the electrons 152 are generated much closer to the backside surface. As a result, many of the electrons 152 are quickly absorbed by the substrate 110 and less electrons 152 are reaching the photodiode. This leads to poor photo sensitivity and poor pixel performance.

The shallow pinned p+ layer 130 helps to collect electrons 152 that are generated near the backside surface. In addition, shallow pinned p+ layer 130 reduces leakage current and provides electrical grounding for the sensor 50. However, this shallow pinned p+ layer 130 seriously out diffuses into p− substrate 110 after the sensor process and when the resistance of p− substrate 110 increases, and thus degrades electrons response to the pixel, especially for blue light.

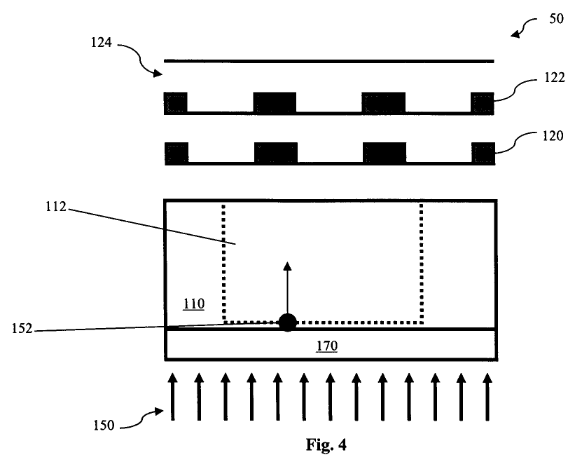

Aspects of the present disclosure provides a method for improving sensitivity of backside illuminated image sensors by first reducing the thickness of the p− substrate prior to implanting the p+ ions at the backside surface of the substrate. Referring to FIG. 4, the resistance of p− substrate 110 is first increased to extend the N-type depletion region 112. In this example, the resistance of p− substrate 110 is increased from about 10 ohm to about 100 ohm. This causes the depletion region 112 to extend to near the backside surface of the p− substrate 110. The typical thickness of the p− substrate 110 before thinning is about 745 um. In one embodiment, the thinning of the p− substrate 110 may be accomplished by grinding down the p− substrate 110 followed by conventional multi-step wet etching to reduce the substrate to a desired thickness.

Once the p− substrate 110 is thinned to a desired thickness, an implantation of p+ ions may be performed on the thinned backside surface of the p− substrate 110 to form a shallow p+ layer 170 at the backside surface. In an illustrative embodiment, the shallow p+ layer 170 may have a thickness of about 100 A to about 1 um and preferably about 100 A to about 1000 A. The implantation energy used to implant shallow p+ layer 170 may be between about 5 KeV to about 500 KeV. The concentration of the shallow p+ layer 170 may be between about 1e16 cm⁻³ to about 1e21 cm⁻³.

It is noted that the conductivity of the depletion region is different from the conductivity of the substrate 110 and doping layer 170. In this exemplary implementation, for example, the conductivity of depletion region 112 is n-type, while the conductivity of substrate 110 and shallow layer 170 both p-type.

By providing a shallow p+ layer 170 at the backside surface, the potential difference between the p− substrate 110 and the p+ layer 170 is increased. Thus, electrons 152 may reach the photodiode more easily without being absorbed by the p− substrate 110. To provide a better electron response to blue light, the thickness of the shallow p+ layer 170 should be preferably less than 1000 A or 0.1 um.

Once the shallow p+ layer 170 is formed, an annealing may be performed using a laser to activate the implantation of p+ ions. In this illustrative embodiment, laser annealing is preferred over conventional annealing techniques, such as Rapid Thermal Annealing (RTA), because the high temperature required for RTA causes damages to the sensor 50. In particular, high temperature over 450° C. may cause the metal layers 120 and 122 of sensor 50 to melt. Since laser annealing only requires high temperature at the backside surface, metal layers 120 and 122 of sensor will not be affected. Once the p+ ion implantation is performed by laser annealing, fewer out diffusions occur from the shallow p+ layer 170 to the p− substrate 110. As a result, the shallow p+ layer 170 provides electrical grounding and reduces leakage current of the sensor 50 and at the same time improves photo sensitivity, especially for blue light.

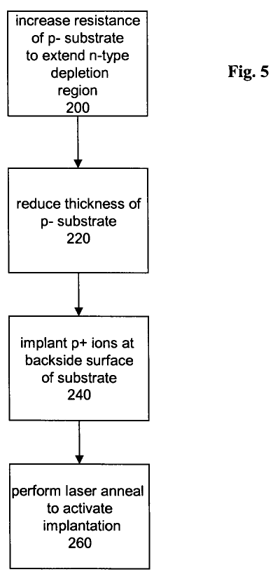

Referring to FIG. 5, a flowchart of an exemplary process for improving sensitivity of backside illuminated image sensor is depicted. The process begins at step 200 to increase the resistance of the p− substrate, which causes the N-type depletion region to extend. The N-type depletion region may be extended fully to the backside surface of the p− substrate. Next, the process proceeds to step 220 to reduce the thickness of p− substrate. The p− substrate may be thinned by first grinding down the p− substrate followed by multi-step wet etching to reduce the substrate to a desired thickness. Once the p− substrate is thinned, the process proceeds to implant p+ ions at the backside surface of the substrate to form a shallow p+ layer. The thickness of the p+ layer is about 100 A to about 1 um and preferably about 100 A to about 1000 A. The implantation energy range is between about 5 KeV to about 500 KeV. The concentration of the shallow p+ layer may be from about 1e16 cm⁻³ to about 1e21 cm⁻³.

Once the p+ ion implantation is complete, the process to step 260 to perform laser annealing at the backside surface to activate the implantation. The laser annealing only requires a high temperature near the backside surface. Therefore, the metal layers of the sensor are not affected. Thus, the process terminates thereafter.

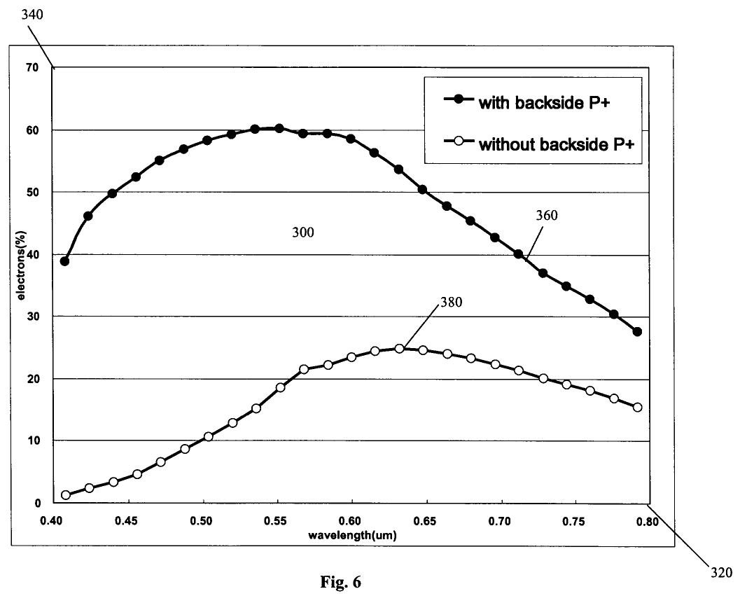

Referring to FIG. 6, a graph illustrating electrons detected by the sensor based on different light wavelength is depicted. In graph 300, X-axis represents various light wavelengths in um. Y-axis 340 represents the percentage of electrons detected by the sensor 50. Curve 360 represents a backside illuminated image sensor with the shallow p+ layer implanted at the backside surface. Curve 380 represents a backside illuminated image sensor without the shallow p+ layer implanted at the backside surface.

As shown in FIG. 6, a greater percentage of electrons are detected by the backside illuminated image senor with the shallow p+ layer implanted at the backside surface. This means that the photo sensitivity of the backside illuminated image senor with the shallow p+ layer is better than the image sensor without the shallow p+ layer. Thus, the sensitivity of backside illuminated image sensor is improved based on the p+ ion implantation at the backside surface, which provides electrical grounding and reduces leakage current.

In summary, aspects of the present disclosure provides a method for improving sensitivity of backside illuminated image sensors. By first reducing the thickness of the p− substrate prior to implanting the p+ ions at the backside surface of the substrate, a shallow p+ layer is formed that provides electrical grounding and reduces leakage current. In addition, by performing laser annealing to activate the implantation, the metal layers of the sensor are not affected. Thus, with the aspects of the present disclosure, photo sensitivity may be improved without affecting performance of the devices and the concerns of out diffusion.

In one embodiment, a backside illuminated image sensor is provided, which comprises a substrate having a first conductivity type and a first potential, a depletion region having a second conductivity type formed within the substrate, a doping layer having the first conductivity type and a second potential formed at a backside surface of the substrate, and a photodiode formed at a front side surface of the substrate.

The depletion region extends to the backside surface of the substrate and comprises second conductivity type ions. The thickness of the substrate is less than 3.5 um. The doping layer comprises first conductivity type ions having a concentration of about 1e16 cm⁻³ to about 1e21 cm⁻³. The thickness of the doping layer is less than about 1 um. The thickness of the doping layer is less than about 1000 A. The first conductivity type is p type and the second conductivity type is n type.

In another embodiment, a method for improving sensitivity of backside illuminated image sensor. A substrate having a first conductivity type and a first potential. A depletion region having a second conductivity type is formed within the substrate. The depletion region is extended. The thickness of the substrate is reduced. First type conductivity ions having a second potential are implanted at backside surface of the substrate to form a doping layer. Laser annealing on the doping layer is performed to activate the first type conductivity ions.

Forming a depletion region comprises implanting second conductivity type ions within the substrate. Extending the depletion region comprises increasing resistance of the substrate to extend the depletion region to near the backside surface of the substrate. Reducing thickness of the substrate comprises grinding down the substrate, and performing a multi-step wet etching to reduce the substrate to a desired thickness. Implanting first type conductivity ions comprises implanting first conductivity type ions using an energy of about 5 KeV to about 500 KeV. The thickness of the substrate is reduce to less than about 3.5 um. The doping layer comprises first conductivity type ions having a concentration of about 1e16 cm⁻³ to about 1e21 cm⁻³. The thickness of the doping layer is less than about 1 um or less than about 1000 A. In one embodiment, the first conductivity type is a p-type and the second conductivity type is n-type

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

Although only a few exemplary embodiments of this invention have been described in detail above, those skilled in the art will readily appreciate that many modifications are possible in the exemplary embodiments without materially departing from the novel teachings and advantages of this invention. It is understood that various different combinations of the above-listed steps can be used in various sequences or in parallel, and there is no particular step that is critical or required. Also, features illustrated and discussed above with respect to some embodiments can be combined with features illustrated and discussed above with respect to other embodiments. Accordingly, all such modifications are intended to be included within the scope of this invention.

What is claimed is:

1. A backside illuminated image sensor comprising:
a substrate having a first conductivity type and a first potential;
a depletion region having a second conductivity type formed within the substrate;
a doping layer having the first conductivity type and a second potential formed at a backside surface of the substrate; and
a photodiode formed at a front side surface of the substrate.

2. The backside illuminated image sensor of claim 1, wherein the depletion region extends to the backside surface of the substrate.

3. The backside illuminated image sensor of claim 1, wherein a thickness of the substrate is less than 3.5 um.

4. The backside illuminated image sensor of claim 1, wherein the depletion region comprises second conductivity type ions.

5. The backside illuminated image sensor of claim 1, wherein the doping layer comprises first conductivity type ions having a concentration of about 1e16 cm⁻³ to about 1e21 cm⁻³.

6. The backside illuminated image sensor of claim 1, wherein a thickness of the doping layer is less than about 1 um.

7. The backside illuminated image sensor of claim 1, wherein a thickness of the doping layer is less than about 1000 A.

8. The backside illuminated image sensor of claim 1, wherein the first conductivity type is p type and the second conductivity type is n type.

9. A method for improving sensitivity of backside illuminated image sensor, the method comprising:
providing a substrate having a first conductivity type and a first potential;
forming a depletion region having a second conductivity type within the substrate;
extending the depletion region;
reducing thickness of the substrate;
implanting first type conductivity ions having a second potential at backside surface of the substrate to form a doping layer; and
performing laser annealing on the doping layer to activate the first type conductivity ions.

10. The method of claim 10, wherein forming a depletion region having a second conductivity type within a substrate comprises:
implanting second conductivity type ions within the substrate.

11. The method of claim 10, wherein extending the depletion region comprises:
increasing resistance of the substrate to extend the depletion region to near the backside surface of the substrate.

12. The method of claim 10, wherein reducing thickness of the substrate comprises:
grinding down the substrate; and
performing a multi-step wet etching to reduce the substrate to a desired thickness.

13. The method of claim 10, wherein implanting first type conductivity ions comprises:
implanting first conductivity type ions using an energy of about 5 KeV to about 500 KeV.

14. The method of claim 10, wherein reducing thickness of the substrate comprises reducing the thickness of the substrate to less than about 3.5 um.

15. The method of claim 10, wherein the doping layer comprises first conductivity type ions having a concentration of about 1e16 cm⁻³ to about 1e21 cm⁻³

16. The method of claim 10, wherein the first conductivity type is a p-type.

17. The method of claim 10, wherein a thickness of the doping layer is less than about 1 um.

18. The method of claim 10, wherein a thickness of the doping layer is less than about 1000 A.

19. The method of claim 10, wherein the second conductivity type is n-type
